(19) United States
(12) Patent Application Publication
(10) Pub. No.: US 2026/0282766 A1
(43) Pub. Date: Sep. 17, 2026

(54) ELECTRONIC DEVICE COMPRISING A MEMORY CIRCUIT BASED ON A PHASE CHANGE MATERIAL

(71) Applicant: STMicroelectronics International N.V., Geneva (CH)

(72) Inventors: Valentin BACQUIE, Grenoble (FR); Madec QUERRE, Grenoble (FR); Loic GANNEREAU, Grenoble (FR); Simon DESMOULINS, Corenc (FR); Sarah RUBECK, Arvillard (FR)

(73) Assignee: STMicroelectronics International N.V., Geneva (CH)

(21) Appl. No.: 19/565,328

(22) Filed: Mar. 12, 2026

(30) Foreign Application Priority Data
Mar. 13, 2025 (FR) FR2502500

(51) Int. Cl. H10N 70/00; H10B 63/10; H10N 70/20

(52) U.S. Cl. CPC H10N 70/8413; H10B 63/10; H10N 70/011; H10N 70/231; H10N 70/8265

(57) ABSTRACT

The present description concerns an electronic device comprising memory cells arranged in an array of rows and columns, each memory cell comprising: a resistive heating element having a lower horizontal portion and an upper vertical portion, the vertical portion being in contact with the horizontal portion; and a layer of a phase-change material common to memory cells of a same row and covering an upper surface of the resistive heating elements, each resistive heating element being covered by an insulating spacer, the insulating spacer being in contact with a vertical flank of the vertical portion of the resistive heating element and with an upper surface of the horizontal portion of the resistive heating element, and the insulating spacers covering two successive resistive heating elements of a same row, being separated by an insulating oxide layer, the insulating layer being in contact with the insulating spacers.

### CROSS-REFERENCE TO RELATED APPLICATIONS

This application claims the priority benefit of French patent application number 2502500, filed on Mar. 13, 2025, entitled “Electronic device comprising a memory circuit based on a phase change material” which is hereby incorporated by reference to the maximum extent allowable by law.

### BACKGROUND

### Technical Field

The present disclosure generally concerns the field of electronic devices and more particularly aims at the field of electronic chips comprising a memory circuit, based on a phase-change material, and at their manufacturing methods.

### Description of the Related Art

A phase-change material is a material having the ability to change crystalline state under the effect of heat, and more specifically to switch between a crystalline state and an amorphous state, which is more highly resistive than the crystalline state. This phenomenon is used to define two memory states, for example 0 and 1, differentiated by the resistance measured through the phase-change material.

There is a use for improving electronic chips comprising a memory circuit based on a phase-change material.

### BRIEF SUMMARY

For this purpose, an embodiment provides an electronic device comprising memory cells arranged in the form of an array of rows and columns, each memory cell comprising:

a resistive heating element comprising a lower horizontal portion and an upper vertical portion, the vertical portion being in contact with the horizontal portion; and

a layer made of a phase-change material, the layer of the phase-change material being common to the memory cells of a same row and covering an upper surface of the resistive heating elements,

each resistive heating element being covered by an insulating spacer, the insulating spacer being in contact with a vertical flank of the vertical portion of the resistive heating element and with an upper surface of the horizontal portion of the resistive heating element, and

the insulating spacers covering two successive resistive heating elements of a same row being separated by an insulating oxide layer, the insulating layer being in contact with said insulating spacers.

According to an embodiment, the layer is made of silicon oxide.

According to an embodiment, the insulating spacers are made of silicon nitride.

According to an embodiment, the insulating spacers comprise a plurality of sub-layers.

According to an embodiment, the sub-layers of the insulating spacer each have a thickness smaller than 15 nm.

According to an embodiment, the phase-change material is a chalcogenide.

According to an embodiment, the resistive heating elements are made of an alloy of nitride, titanium, and silicon.

According to an embodiment, the insulating spacers have a thickness in the range from 20 nm to 30 nm.

According to an embodiment, each resistive heating element is in contact with the insulating layer by a side flank, opposite to the vertical portion, of the horizontal portion of the resistive heating element.

According to an embodiment, the device further comprises an upper electrode on the layer made of the phase-change material opposite to the resistive heating element, and a masking layer on the upper electrode,

the layer made of the phase-change material, the upper electrode, and the masking layer being common to the memory cells of a same row and covered by an encapsulation layer, the encapsulation layer covering an upper surface of the masking layer and side flanks of the masking layer, of the upper electrode, and of the layer made of the phase-change material,

wherein the insulating spacers, the masking layer, and the encapsulation layer each comprise a plurality of silicon nitride sub-layers.

Another embodiment provides a method of manufacturing an electronic device comprising memory cells arranged in the form of an array of rows and columns, comprising the following consecutive steps:
a) forming of trenches in a first layer;
b) deposition of a layer made of an electrically-resistive material;
c) deposition of a first insulating layer on the layer made of the electrically-resistive material;
d) anisotropic etching of the first insulating layer and of the layer made of the electrically-resistive material so as to only let them remain on the flanks of the first layer, and to form, in the layer made of the electrically-resistive material, resistive heating elements and, in the first insulating layer, insulating spacers;
e) deposition of an insulating oxide layer in the trenches, so as to completely fill them;
f) removal of an upper portion of the insulating layer, of the spacers, and of the resistive heating elements so as to expose the upper surface of the first layer.

According to an embodiment, during step c), the first insulating layer is deposited by a pulsed plasma-enhanced chemical vapor deposition method.

According to an embodiment, during step c), the power of the plasma alternates between a high power and a low power.

According to an embodiment, the first insulating layer is formed by the successive deposition of a plurality of sub-layers.

According to an embodiment, the sub-layers have a thickness lower than 15 nm.

According to an embodiment, the method further comprises, after step f), the following successive steps:

deposition of an upper electrode on the layer made of the phase-change material;

deposition of a masking layer on the upper electrode;

etching in such a way as to create, in the masking layer, the upper electrode, and the layer made of the phase-change material, rows; and

deposition of an encapsulation layer covering an upper surface of the masking layer and side flanks of the masking layer, of the upper electrode, and of the layer made of the phase-change material.

According to an embodiment, the masking layer and/or the encapsulation layer are deposited according to a pulsed plasma-enhanced chemical vapor deposition method.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 is a cross-section view, partial and simplified, illustrating an example of an electronic device;

FIGS. 2A-2J, and 2K are views, partial and simplified, illustrating steps of an example of a method of manufacturing an electronic device according to a first embodiment;

FIGS. 3A and 3B are views, partial and simplified, illustrating steps of an example of a method of manufacturing an electronic device according to a second embodiment;

FIG. 4 is a view, partial and simplified, of an example of an electronic device according to a third embodiment;

FIG. 5 is a view, partial and simplified, of an example of an electronic device according to a fourth embodiment; and

FIG. 6 is a view, partial and simplified, of an example of an electronic device according to a fifth embodiment.

### DETAILED DESCRIPTION

The same elements have been designated by the same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

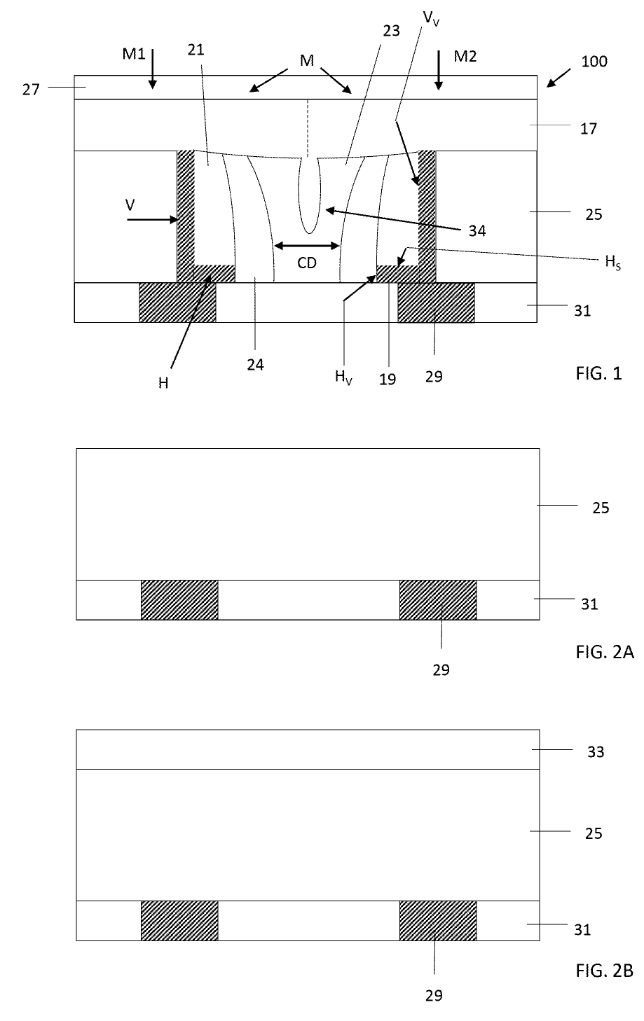

FIG. 1 is a cross-section view, partial and simplified, illustrating an example of an electronic device 100.

Device 100 is, for example, an electronic chip.

Device 100 comprises a memory circuit comprising a plurality of memory cells M organized, in top view, in an array of rows and columns. It is respectively spoken of word lines (WL) and of bit lines (BL). As an example, each memory cell M is located at the intersection of a bit line and of a word line.

As an example, the memory cells M shown in FIG. 1 are memory cells M of a same bit line BL. In FIG. 1, only two memory cells M1, M2 are shown. In practice, a memory circuit may comprise a number of memory cells M, per bit line, greater than two.

Memory cells M are phase-change memory cells. Each cell M comprises a layer 17 made of a phase-change material, for example a chalcogenide material, for example an alloy of germanium, antimony, and tellurium (GeSbTe) known as GST. Layer 17 has, for example, a thickness in the range from 30 nm to 100 nm, for example, in the order of 50 nm. Each layer 17 extends, for example, in the bit line direction. The memory cells M of a same bit line comprise a common layer 17. Thus, device 100 comprises, for example, as many layers 17 as bit lines.

In each memory cell M, the phase-change material is controlled by an electrically-resistive element 19. Resistive element 19 is located under phase-change material 17. Element 19 is for example in contact, by its upper surface, with the lower surface of layer 17. As an example, element 19 is a heating element.

Each element 19 is “L”-shaped in the cross-section plane of FIG. 1. Each element 19 thus comprises, in its lower portion, a horizontal portion H, and in an upper portion, a vertical portion V. The vertical portion V and the horizontal portion H of each element 19 are in contact with each other. As an example, the vertical and horizontal portions are in contact by their side flanks. Elements 19 do not all have, within a same bit line, for example, the same orientation. As an example, certain elements 19 have the shape of an inverted “L”, that is, their horizontal portion H extends, in the orientation of FIG. 1, to the left of vertical portion V. As an example, each bit line comprises a succession of elements 19 with an alternation of “L”-shaped elements 19 and of inverted “L”-shaped elements 19. As an example, each element 19 is symmetrical with its two neighbors in a same bit line, along a vertical plane parallel to the vertical portion V of elements 19. Two consecutive elements 19 of a same bit line thus have either their horizontal portions H facing each other or their vertical portions V facing each other.

Resistive element 19 is, for example, made of a metallic material, for example of an alloy of nitride, silicon, and titanium (TiSiN).

Two neighboring resistive elements 19 of a same bit line, having their horizontal portions H face to face, are separated by two first insulating spacers or insulating layers 21, each coating a resistive element 19. Each spacer 21 is for example in contact with an element 19.

More specifically, each spacer 21 covers, and is in contact with, the upper surface of the horizontal portion H of each element 19. Each spacer 21 further covers, and is in contact with, a flank of the vertical portion V of element 19. Each spacer 21 extends, for example, along a portion only of the height of element 19. Each spacer 21 extends, for example, along the entire height of the vertical portion V of element 19 not covered by horizontal portion H. Spacers 21 are for example made of silicon nitride.

As an example, spacers 21 have a thickness, taken in the plane of the upper surface of the horizontal portion H of element 19, in the range from 20 nm to 30 nm, for example in the order of 25 nm.

Two neighboring resistive elements 19 of a same bit line, having their horizontal portions H face to face, are further separated by another insulating layer 23. As an example, layer 23 extends between the spacers 21 coating elements 19. Layer 23 extends, for example, along the entire height of elements 19. Layer 23 is for example made of silicon oxide.

In the example of FIG. 1, each layer 23 is separated from each of the two spacers 21 which surround it by a second spacer or layer 24. Thus, insulating layer 23 for example coats the side flanks of two neighboring spacers 24. As an example, each layer 23 has its two lateral flanks in contact with two neighboring spacers 24. Spacers 24 extend, for example, along the entire height of layer 23.

Each spacer 24 has, for example, one of its side flanks in contact with the side flank of a spacer 21. Each spacer 24 has, for example, the other of its side flanks in contact with the side flank of a layer 23.

As an example, in a lower portion, each spacer 24 further covers and is in contact with the side flank of the horizontal portion H of element 19, opposite to the vertical portion, not covered by spacer 21. As an example, layers 23 have their upper surfaces in contact with the lower surface of layer 17.

As an example, spacers 24 are made of silicon nitride.

As an example, spacers 24 have a thickness, taken in the plane of their lower surfaces, in the range from 20 nm to 30 nm, for example in the order of 25 nm.

Two neighboring resistive elements 19 of the same bit line, having their vertical portions V facing each other, are for example separated by an insulating layer 25. Insulating layer 25 for example covers the vertical flanks of the vertical portions V of the two neighboring elements 19 and is for example in contact with them. As an example, layer 25 covers, for each element 19, the flank of its vertical portion V, opposite to its horizontal portion H. Layer 25 extends, for example, along the entire height of elements 19.

As an example, the lower surfaces of elements 19, of layers 23, and of spacers 24 are coplanar. As an example, the upper surfaces of elements 19, of spacers 24, of layers 23, and of spacers 21 are coplanar. As an example, heating elements 19 have a height in the range from 30 nm to 100 nm, for example in the order of 60 nm.

For example, layer 17 is topped by a layer 27 made of a conductive material, for example of a metallic material. More specifically, the upper surface of each layer 17 is for example at least partially covered, for example entirely covered, by a layer 27. Each layer 27 extends, preferably in the bit line direction, along the entire length of layer 17.

For example, in each memory cell M, metal element 19 and layer 27 respectively form a lower electrode and an upper electrode of memory cell M, and more specifically electrodes of the variable-resistance resistive element formed by layer 17 made of the phase-change material. As an example, the memory cells M of the same bit line are topped by a same layer 27. In other words, the upper electrodes 27 of memory cells M of a same bit line are interconnected.

As an example, each memory cell M is electrically connected to a selection transistor, not shown. For example, each memory cell is coupled to the selection transistor which is associated therewith via a conductive via 29. As an example, the upper surface of via 29 is in contact with the lower surface of the element 19 of the associated memory cell M. As an example, vias 29 are made of a conductive material, for example metallic, for example of tungsten. As an example, vias 29 are surrounded by an insulating layer 31. Insulating layer 31 is for example made of oxide, for example of silicon oxide.

As an example, vias 29 extend through an interconnection stack located between the selection transistors and memory cells M.

The memory cells M of neighboring bit lines are, for example, insulated from each other by an insulating layer, not shown, for example made of a material having a low dielectric constant or of an oxide, for example, of silicon oxide.

In such a device, during the deposition of layer 23, in the opening formed between the spacers 24 of two consecutive memory cells of a same bit line, a bubble-like void 34 with no layer 23 may form in layer 23. The forming of such a void 34 can be explained by the fact that the width CD between spacers 24 is small, which prevents a proper filling of the opening by layer 23.

Voids 34 may open onto the upper surface of layer 23. During the forming of the layer made of the phase-change material 17, this layer 17 may intrude into cavities 34, thus causing defects in memory cells M.

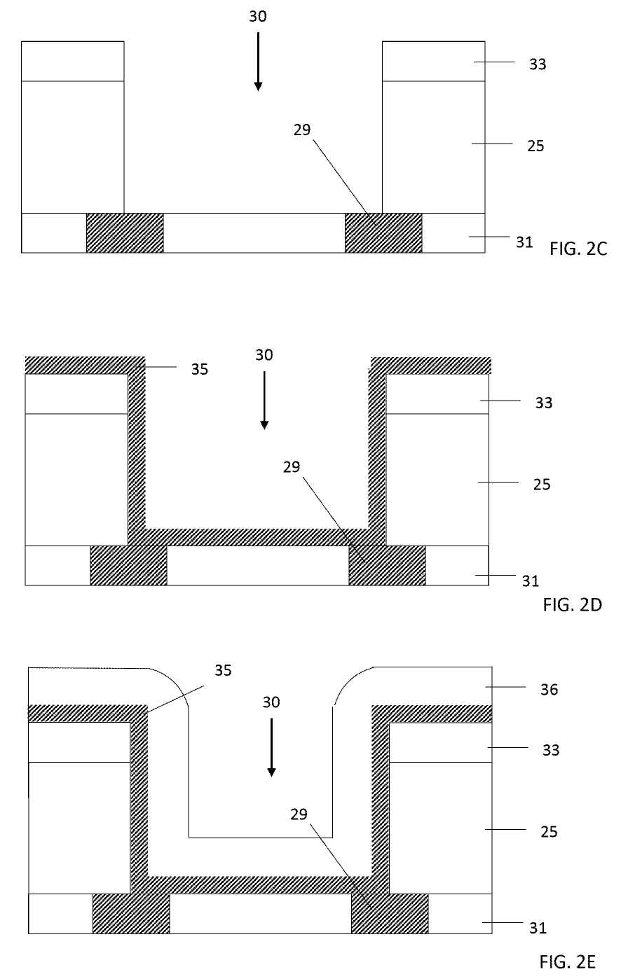

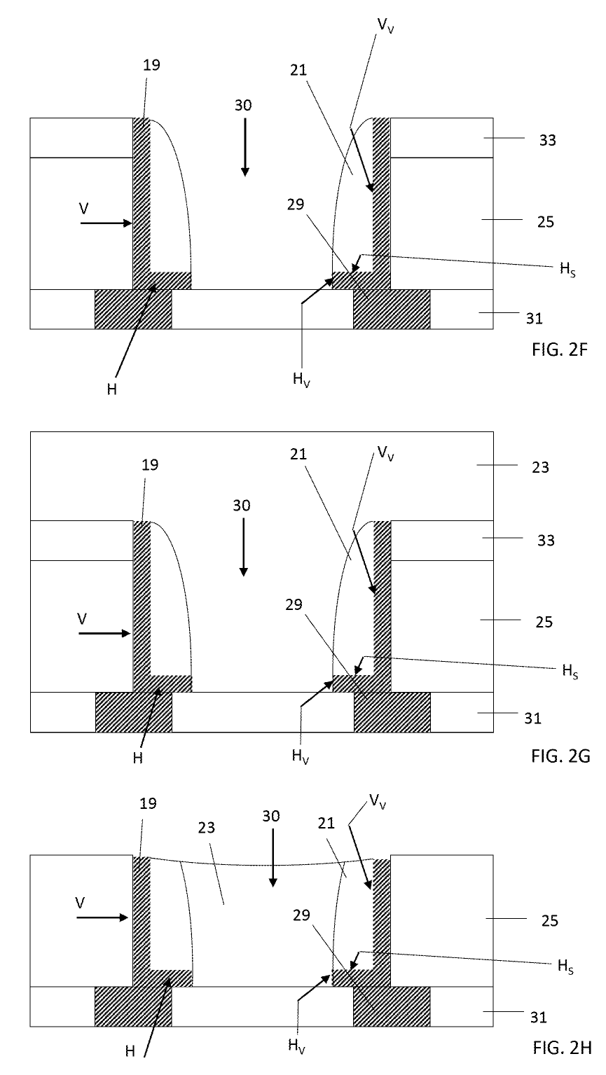

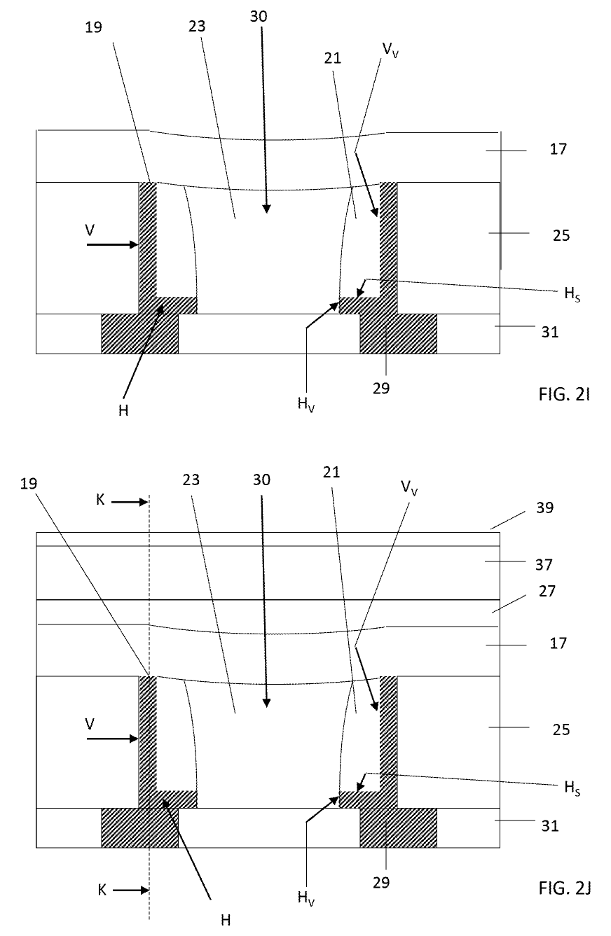

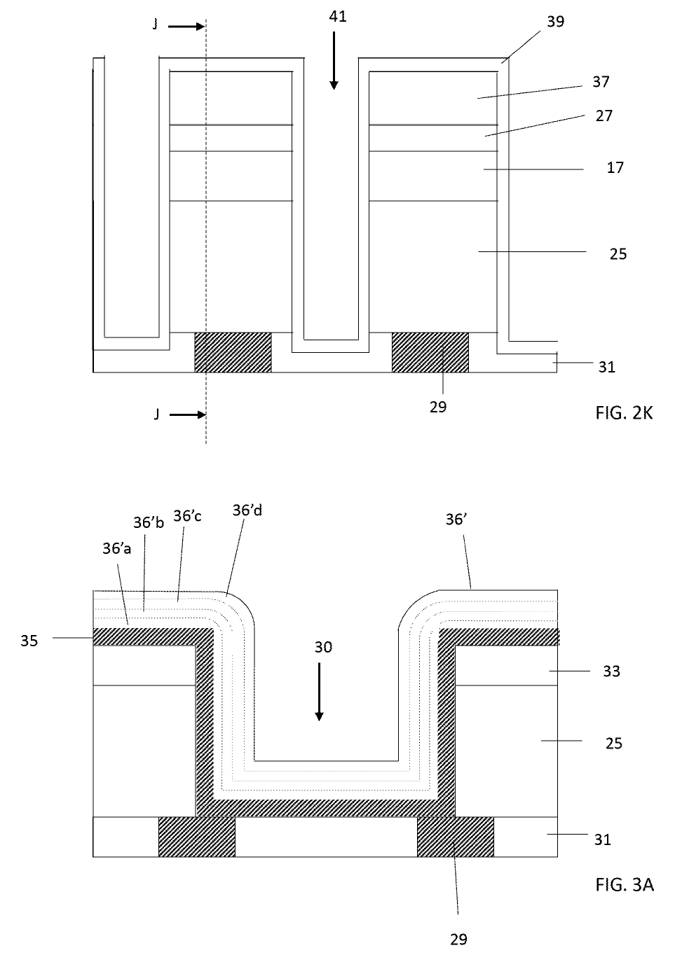

FIGS. 2A-2J, and 2K are views, partial and simplified, illustrating steps of an example of a method of manufacturing an electronic device according to a first embodiment.

The first embodiment enables to increase width CD by removing the second spacer 24.

FIG. 2A shows an initial structure comprising insulating layer 25. The initial structure further comprises conductive vias 29. In the initial structure, vias 29 are, for example, surrounded by layer 31. Conductive vias 29 are, for example, in the initial structure, topped by insulating layer 25.

In this embodiment, insulating layer 25 is for example made of a nitride, for example of silicon nitride. As an example, layer 25 has a thickness in the range from 30 nm to 100 nm, for example in the order of 60 nm.

FIG. 2B illustrates a structure obtained at the end of a step of deposition of a layer 33 on the upper surface of the structure shown in FIG. 2A.

Layer 33 is, for example, an etch stop layer. Layer 33 is for example made of an insulating material, for example of an oxide, for example of silicon oxide. Layer 33 is for example made of a material different from the material of layer 25. Layer 33 for example covers layer 25 over its entire surface. As an example, layer 33 is in contact, by its lower surface, with the upper surface of layer 25.

For example, layer 33 has a thickness in the range from 25 nm to 35 nm, for example in the order of 30 nm.

FIG. 2C illustrates a structure obtained at the end of a step of etching of the layers 25 and 33 of the structure shown in FIG. 2B.

More specifically, during this step, layers 25 and 33 are for example locally etched to form trenches 30 in the stack of layers 25 and 33. During this step, the stack of layers 25 and 33 is locally removed from at least part of the upper surface of each via 29. During this step, part of the upper surface of layer 31 and of vias 29 is for example exposed. At the end of this step, vias 29 thus have their upper surfaces at least partially exposed.

FIG. 2D illustrates a structure obtained at the end of a step of forming of a layer 35 made of the material of resistive heating element 19 on the upper surface of the structure illustrated in FIG. 2C.

During this step, layer 35 is for example deposited over the entire upper surface of the structure shown in FIG. 2C. Layer 35 is for example conformally deposited.

As an example, during this step, layer 35 is deposited so that it covers the upper surface of layer 33 and the flanks of layer 33 and of layer 25 and, in trenches 30, the upper surface of layer 31 and of via 29 not covered by layer 25. As an example, layer 35 is deposited in contact with the above-mentioned layers.

As an example, layer 35 is deposited with a thickness in the range from 2 nm to 6 nm, for example in the order of 4 nm.

FIG. 2E illustrates a structure obtained at the end of the deposition of a layer 36 made of the material of spacers 21 on the upper surface of the structure shown in FIG. 2D.

During this step, layer 36 is for example deposited so as to cover the entire surface of the upper side of layer 33. As an example, layer 36 is conformally deposited. For example, layer 36 is deposited with a thickness in the range from 10 nm to 40 nm.

FIG. 2F illustrates a structure obtained at the end of a step of etching of the layers 36 and 35 of the structure shown in FIG. 2E.

More specifically, during this step, layer 36 is etched in such a way that it only remains on the flanks of the stack of layers 25 and 35, forming spacers 21. Layer 36 is, during this step, for example removed from the upper surface of layer 33 and from the upper surface of vias 29 and of insulating layer 31.

Further, during this step, layer 35 is etched, only remaining in the portions where it is protected by spacers 21, forming elements 19. As an example, the etching is, during this step, stopped when the upper surface of layer 33 is exposed.

As an example, the etching corresponds to a dry etching. As an example, the etching corresponds to anisotropic etching, for example a plasma etching.

Further, at the end of this step, each spacer 21 is in contact with the vertical flank V_{V} of the vertical portion V of an element 19 and with the upper surface H_{S} of the horizontal portion H of the same element 19.

FIG. 2G illustrates a structure obtained at the end of a step of deposition of a layer 23 on the upper surface of the structure shown in FIG. 2F.

More particularly, during this step, layer 23 is for example formed over the entire wafer. As an example, layer 23 covers the upper surface of layer 31 and vias 29, the upper surface of layer 33, of spacers 21, and of elements 19. Further, in this embodiment, layer 23 covers, in each of trenches 30, the side flank, opposite to vertical portion V, of the horizontal portion H of each of the two elements 19 facing each other. In this embodiment, layer 23 is in contact with the side flank H_{V}, opposite to vertical portion V, of the horizontal portion H of each of the two elements 19 facing each other with their horizontal surfaces H. Layer 23 is, in tis embodiment and conversely to the example of FIG. 1, formed in contact with the spacers 21 coating the elements 19 of two successive memory cells M.

As an example, layer 23 is deposited with a thickness sufficiently large to completely fill the trenches 30 between the stacks of layers 25 and 33. Layer 23 for example has a thickness in trenches 30 greater than 110 nm, for example in the order of 125 nm

Layer 23 is, in this embodiment, made of an oxide, for example of silicon oxide.

FIG. 2H illustrates a structure obtained at the end of a step of removal of an upper portion of the structure shown in FIG. 2G.

More specifically, during this step, an upper portion of the structure shown in FIG. 2G is removed to expose the upper surface of layer 25. As an example, layer 33 and an upper portion of layer 23, of spacers, and of elements 19 are then removed in one and the same step. The removal is, during this step, carried out by mechanical polishing, for example by chemical-mechanical polishing (CMP).

FIG. 2I illustrates a structure obtained at the end of a step of deposition of layer 17 on the upper surface of the structure shown in FIG. 2H.

More specifically, during this step, layer 17 is deposited in such a way as to cover the entire upper surface of the structure shown in FIG. 2H. As an example, layer 17 is in contact with the upper surface of the structure shown in FIG. 2H. More particularly, the upper surface of layer 25, the upper surface of layer 23, and the upper surface of spacers 21 and of elements 19 are covered by layer 17.

FIGS. 2J and 2K illustrate a structure obtained at the end of a step of forming of electrode 27, of a masking layer 37, and of an encapsulation layer 39 on the upper surface of the structure shown in FIG. 2I, FIG. 2J being a view along the cross-section plane JJ of FIGS. 2K and 2K being a view along the cross-section plane KK of FIG. 2J.

During this step, electrode 27 is formed for example on the upper surface of layer 17, for example, in contact, by its lower surface, with the upper surface of layer 17.

Further, during this step, layer 37 is for example formed on the upper surface of layer 27, for example, in contact, by its lower surface, with the upper surface of layer 27. Layer 37 is for example formed over the entire upper surface of layer 27. Masking layer 37 is for example made of a nitride, for example of silicon nitride. As an example, layer 37 has a thickness in the order of 15 nm. Layer 37 is deposited, for example, by a nanometric deposition method.

Layer 37 for example comprises a plurality of sub-layers. As an example, layer 37 is deposited by a pulsed plasma-enhanced chemical vapor deposition (PECVD) method. This deposition method is similar to the PECVD deposition method, with the difference that the power of the plasma is not constant for the entire deposition time. The power of the plasma is, in this method, pulsed, that is, it follows pulses. In this method, the power of the plasma alternates between a high power and a low power. As an example, the high power is in the range from 80 W to 200 W, for example in the order of 107 W. As an example, the low power is substantially zero. During the deposition of layer 37, the precursor gas comprises, for example, trisilylamine (TSA), ammonia (NH₃), nitrogen (N₂), or a combination of two or more of these elements.

The pulse frequency is, for example, in the range from 800 Hz to 1,500 Hz, for example in the order of 1000 Hz. As an example, over the duration of the deposition of layer 37, the plasma is ignited, for example between 5% and 20% of the time, for example around 10% of the time. The deposition of layer 37 has for example a duration longer than 30 seconds, for example in the range from 60 seconds to 120 seconds and is, for example in the order of 91 seconds. During this step, layer 37 is for example deposited with a thickness smaller than 15 nm, for example in the order of 11 nm.

As an example, an 11-nm deposition of layer 37 is achieved when:

the power of the plasma is, at its highest value, 107 W;

the pulse frequency is 1,000 Hz;

the plasma is activated for 10% of the time; and

the deposition time is 91 seconds.

As an example, at the end of the deposition of layer 37, the latter is submitted to a treatment step enabling to densify layer 37 with nitrogen. In other words, layer 37 undergoes, at the end of its deposition, a step enabling it to increase its nitrogen content. As an example, this treatment consists of exposing the surface of layer 37 to a nitrogen and helium plasma.

The sequence of a deposition according to the pulsed PECVD method followed by a treatment step corresponds to a pulsed PECVD deposition cycle.

As a variant, layer 37 is formed by a non-pulsed PECVD deposition method.

At the end of the deposition of layers 27 and 37, layer 37 is locally etched in such a way as to create, in layer 37, through openings extending all the way to the surface of layer 27. A the end of the forming of the openings in layer 37, trenches 41 are formed in the resulting structure. More specifically, during this step, the forming of trenches 41 is performed while masking layer 37 acts as an etch mask.

As an example, trenches 41 are formed from the upper surface of layer 27 in the stack of memory cells M until they reach insulating layer 31. As an example, the etching is stopped when trenches 41 emerge into insulating layer 31.

During this step, the forming of trenches 41 enables to form the bit lines.

At the end of this step, layer 37 has a thickness decreased as compared with what has been previously described during the deposition of layer 37. Layer 37 indeed has, at the end of this step, a thickness smaller than 10 nm, for example smaller than 7 nm, for example in the order of 5 nm.

Further, during this step, encapsulation layer 39 is formed on the upper surface of the structure. Each memory cell M is for example covered by an encapsulation layer 39 protecting, for example, layer 17 made of the phase-change material from oxidation. As an example, encapsulation layer 39 covers and is for example in contact with the upper surface of layer 37 and the flanks of layers 37, 27, 17, and 25. Encapsulation layer 39 is for example made of a dielectric material. Encapsulation layer 39 is for example made of a nitride, for example of silicon nitride. Encapsulation layer 39 for example has a thickness in the range from 20 nm to 50 nm, for example in the order of 33 nm. More specifically, during this step, layer 39 is deposited on the upper surface of layer 37 and in trenches 41, on the side flanks of the stack of layers 37, 27, 17, and 25. As an example, layer 39 is further deposited at the bottom of trenches 41 on the upper surface of layer 31.

Layer 39 is for example deposited according to a conformal deposition method. As an example, layer 39 comprises a plurality of sub-layers. As an example, layer 39 is deposited according to a method of pulsed deposition PECVD similarly to what has been described for layer 37.

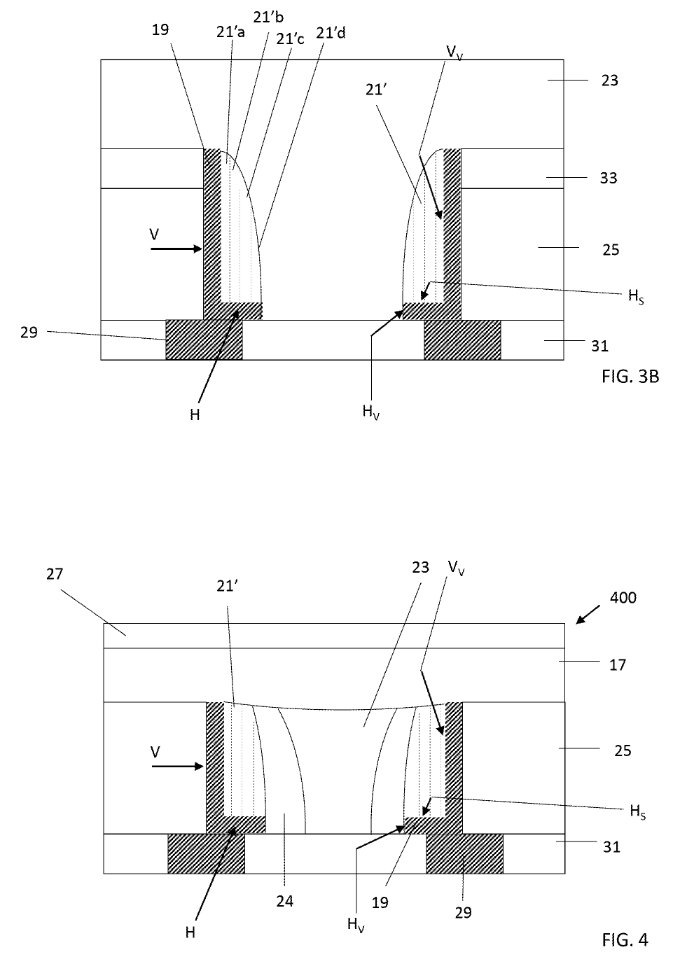

FIGS. 3A and 3B are views, partial and simplified, illustrating steps of an example of a method of manufacturing an electronic device according to a second embodiment.

More particularly, the method according to the second embodiment is similar to the method according to the first embodiment illustrated in FIGS. 2A-2I, with the difference that the steps illustrated in FIGS. 2E and 2F are replaced by steps 3A and 3B. During these steps, layer 36 is replaced by a layer 36′ comprising a plurality of sub-layers 36′a, 36′b, 36′c, 36′d.

FIG. 3A illustrates a structure obtained at the end of a step of deposition of layer 36′ on the upper surface of the structure shown in FIG. 2D.

The sub-layers 36′a, 36′b, 36′c, 36′d of layer 36, for example, are deposited by pulsed PECVD, similarly to what has been described for layer 37.

As an example, a 5-nm deposition is performed when:

the power of the plasma is, at its highest value, 107 W;

the pulse frequency is 1,000 Hz;

the plasma is activated for 10% of the time; and

the deposition time is 41 seconds.

In FIG. 3A, four sub-layers 36′a, 36′b, 36′c, and 36′d have been shown for layer 36′. In practice, the number of sub-layers may be different from 4 and may be equal to 2, or equal to 3 or greater than 4.

As an example, all the sub-layers of layer 36′ have the same thickness. The thickness of layer 36′ is, for example, in this embodiment a function of the number of sub-layers.

As a variant of the embodiment shown in FIG. 3A, layer 36′ may be a monolayer formed by pulsed PECVD.

FIG. 3B illustrates a structure obtained at the end of a step of etching of the layers 36′ and 35 shown in FIG. 3A in such a way as to form spacers 21′ comprising a plurality of sub-layers 21′a, 21′b, 21′c, 21′d and elements 19. This step is identical to the step of etching of layers 36 and 35 shown in FIG. 2F, to within the difference in thickness of layer 36′.

At the end of this step, spacers 21′ have, for example, a thickness, taken at the interface between spacers 21′ and the upper surface of the horizontal portion H of element 19, in the range from 20 nm to 30 nm, for example in the order of 25 nm.

An advantage of the present embodiment is that it enables to deposit layer 36′ with a smaller thickness as compared with a layer 36 deposited by non-pulsed PECVD.

An advantage of the present embodiment is that a spacer 21′ deposited by pulsed PECVD has better thermal insulation than a spacer 21 of same thickness but deposited by a non-pulsed PECVD method. Indeed, in this embodiment, each spacer 21′ comprises, between each of sub-layers 21′a, 21′b, 21′c, and 21′d, an interface, each of these interfaces increasing the thermal insulation of spacer 21′.

While, in the first and second embodiments, the removal of the second spacers 24 leads to an increase in width CD, it may be possible to achieve this effect, rather than by the removal of the second spacers, by the decrease in the thickness of one and/or the others of the first 21 and second 24 spacers of FIG. 1. In other words, it may be provided to keep spacers 24 as shown in FIG. 1, but to decrease their thickness and/or decrease the thickness of spacers 21.

FIG. 4 is a view, partial and simplified, of an example of an electronic device 400 according to a third embodiment. More particularly, in this embodiment, it is provided to keep the second spacers 24 and to form the first spacers by a pulsed PECVD method, decreasing their thicknesses.

Thus, device 400 is similar to the device 100 shown in FIG. 1, with the difference that spacers 21 are replaced by spacers 21′ formed by pulsed PECVD. In this embodiment, spacers 21′ have a thickness smaller than the thickness of the spacers 21 shown in FIG. 1.

Spacers 21′ can thus have a thickness smaller than 15 nm, for example in the order of 11 nm or in the order of 5 nm. Spacers 24 have, in this embodiment, for example, a thickness identical to that which has been described in relation with FIG. 1, that is, a thickness in the range from 20 nm to 30 nm, for example in the order of 25 nm.

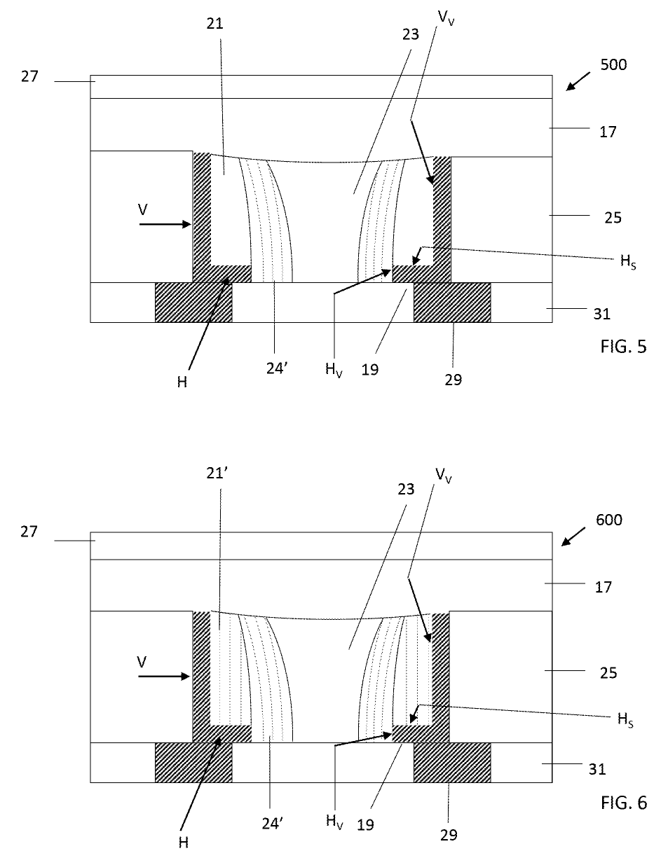

FIG. 5 is a view, partial and simplified, of an example of an electronic device 500 according to a fourth embodiment. More particularly, in this embodiment, it is provided to keep the second spacers 24 and to form them by a pulsed PECVD method, decreasing their thicknesses.

Thus, device 500 is similar to the device 100 shown in FIG. 1, with the difference that spacers 24 are replaced by spacers 24′ formed by pulsed PECVD. In this embodiment, spacers 24′ have a thickness smaller than the thickness of the spacers 24 shown in FIG. 1.

Spacers 24′ may thus have a thickness smaller than 15 nm, for example in the order of 11 nm or in the order of 5 nm. In this embodiment, spacers 21 have, for example, a thickness identical to what has been described in relation with FIG. 1, that is, a thickness in the range from 20 nm to 30 nm, for example in the order of 25 nm.

FIG. 6 is a view, partial and simplified, of an example of an electronic device 600 according to a fifth embodiment. More particularly, in this embodiment, it is provided to keep the second spacers 24 and to form the first and second spacers by a pulsed PECVD method, decreasing their thicknesses.

Thus, device 600 is similar to the device 100 shown in FIG. 1, with the difference that spacers 21 and 24 are respectively replaced by pulsed PECVD spacers 21′ and 24′. In this embodiment, spacers 21′ and 24′ for example each have a thickness smaller respectively than the thicknesses of the spacers 21 and 24 shown in FIG. 1.

Spacers 21 and 24 can thus each have a thickness for example smaller than 15 nm, for example in the order of 11 nm or in the order of 5 nm.

Another way of limiting risks of failure linked to the presence of voids 34 in layer 23 is to ensure the presence of voids 34 but to control their depth in opening 30 so that they do not emerge onto the upper surface of layer 23.

An increase in the thickness of one and/or other of spacers 21 and 24 to a certain extent results in the forming of a void 34 between the two elements 19, but that the voids formed do not emerge onto the upper surface of layer 23. In this example, spacers 21 and 24 each have a thickness greater than or equal to 20 nm, for example greater than or equal to 25 nm. Such non-through voids 34 thus increase the thermal insulation between two consecutive elements 19 without damaging memory cells M.

This variant, which consists in increasing the thickness of one and/or other of the first and second spacers, is for example compatible with the forming of one or the other of the spacers by the pulsed PECVD method as described in relation with FIGS. 4-6.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

An electronic device including memory cells (M) is arranged in the form of an array of rows and columns, each memory cell (M) is summarized as including: a resistive heating element (19) including a lower horizontal portion (H) and an upper vertical portion (V), the vertical portion (V) being in contact with the horizontal portion (H); and a layer made of a phase-change material (17), the layer of the phase-change material being common to the memory cells (M) of a same row and covering an upper surface of the resistive heating elements (19), each resistive heating element (19) being covered by an insulating spacer (21; 21′), the insulating spacer (21; 21′) being in contact with a vertical flank (V_{V}) of the vertical portion (V) of the resistive heating element (19) and with an upper surface (H_{S}) of the horizontal portion (H) of the resistive heating element (19), and the insulating spacers (21; 21′) covering two successive resistive heating elements (19) of a same row, being separated by an insulating oxide layer (23), the insulating layer (23) being in contact with said insulating spacers (21; 21′).

The layer (23) is made of silicon oxide.

The insulating spacers (21; 21′) are made of silicon nitride.

The insulating spacers (21′) include a plurality of sub-layers (21′a, 21′b, 21′c, 21′d).

The sub-layers (21′a, 21′b, 21′c, 21′d) of the insulating spacers (21′) each have a thickness smaller than 15 nm.

The phase-change material (17) is a chalcogenide.

The resistive heating elements (19) are made of an alloy of nitride, titanium, and silicon.

The insulating spacers (21; 21′) have a thickness in the range from 20 nm to 30 nm.

Each resistive heating element (19) is in contact with the insulating layer (23) by a side flank (H_{V}), opposite to the vertical portion (V), of the horizontal portion (H) of the resistive heating element (19).

The device further includes an upper electrode (27) on the layer made of the phase-change material (17) opposite to the resistive heating element (19) and a masking layer (37) on the upper electrode (27), the layer made of the phase-change material (17), the upper electrode (27), and the masking layer (37) being common to the memory cells of a same row and covered by an encapsulation layer (39), the encapsulation layer (39) covering an upper surface of the masking layer (37) and side flanks of the masking layer (37), of the upper electrode (27), and of the layer made of the phase-change material (17), wherein the insulating spacers (21′), the masking layer (37), and the encapsulation layer (39) each include a plurality of silicon nitride sub-layers.

A method of manufacturing an electronic device including memory cells (M) arranged in the form of an array of rows and columns, is summarized as including the following consecutive steps: a) forming of trenches (30) in a first layer (25); b) deposition of a layer made of an electrically-resistive material (35); c) deposition of a first insulating layer (36) on the layer made of the electrically-resistive material (35); d) anisotropic etching of the first insulating layer (36) and of the layer made of the electrically-resistive material (35) so as to only let them remain on the flanks of the first layer (25) and to form, in the layer of the electrically-resistive material (35), resistive heating elements (19) and, in the first insulating layer (36), insulating spacers (21); e) deposition of an insulating oxide layer (23) in the trenches (30), so as to completely fill them; f) removal of an upper portion of the insulating layer (23), of the spacers (21), and of the resistive heating elements (19) so as to expose the upper surface of the first layer (25).

During step c), the first insulating layer (36′) is deposited by a pulsed plasma-enhanced chemical vapor deposition method.

During step c), the power of the plasma alternates between a high power and a low power.

The first insulating layer (36′) is formed by the successive deposition of a plurality of sub-layers (36′a, 36′b, 36′c, 36′d).

The sub-layers (36′a, 36′b, 36′c, 36′d) have a thickness smaller than 15 nm.

The method further includes, after step f), the following successive steps: deposition of an upper electrode (27) on a layer made of a phase-change material (17); deposition of a masking layer (37) on the upper electrode (27); etching in such a way as to create, in the masking layer (37), the upper electrode (27), and the layer made of the phase-change material (17), rows; and deposition of an encapsulation layer (39) covering an upper surface of the masking layer (37) and the side flanks of the masking layer (37), of the upper electrode (27), and of the layer made of the phase-change material (17).

The masking layer (37) and/or the encapsulation layer (39) are deposited according to a pulsed plasma-enhanced chemical vapor deposition method.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising memory cells arranged in the form of an array of rows and columns, each memory cell including:
a resistive heating element including a horizontal portion and a vertical portion, the vertical portion being in contact with the horizontal portion; and
a layer made of a phase-change material, the layer of the phase-change material being common to the memory cells of a same row and covering a first surface of the resistive heating elements,
each resistive heating element being covered by a first insulating spacer, the insulating spacer being in contact with a vertical flank of the vertical portion of the resistive heating element and with a first surface of the horizontal portion of the resistive heating element, each insulating spacer having a first, rounded surface opposite the vertical flank of the vertical portion, and
the first insulating spacers covering two successive resistive heating elements of a same row, being separated by an insulating oxide layer, the insulating layer being in contact with the first, rounded surfaces of the insulating spacers.

2. The electronic device according to claim 1, wherein:
the insulating layer is in contact with first insulating spacers covering two successive resistive heating elements of a same row; and
each resistive heating element is in contact with the insulating layer by a side flank, opposite to the vertical portion, of the horizontal portion of the resistive heating element.

3. The electronic device according to claim 1, wherein the layer is made of silicon oxide.

4. The electronic device according to claim 1, wherein the first insulating spacers are made of silicon nitride.

5. The electronic device according to claim 1, wherein the first insulating spacers include a plurality of sub-layers.

6. The electronic device according to claim 5, wherein the sub-layers of the insulating spacers each have a thickness smaller than 15 nm.

7. The electronic device according to claim 1, wherein the phase-change material is a chalcogenide.

8. The electronic device according to claim 1, wherein the resistive heating elements are made of an alloy of nitride, titanium, and silicon.

9. The electronic device according to claim 1, wherein the first insulating spacers have a thickness in a range of 20 nm and 30 nm.

10. The electronic device according to claim 1, further comprising:
a first electrode on the layer made of the phase-change material opposite to the resistive heating element; and
a masking layer on the first electrode,
the layer made of the phase-change material, the upper electrode, and the masking layer being common to the memory cells of a same row and covered by an encapsulation layer, the encapsulation layer covering a first surface of the masking layer opposite the first electrode and side flanks of the masking layer, of the first electrode, and of the layer made of the phase-change material,
wherein the first insulating spacers, the masking layer, and the encapsulation layer each include a plurality of silicon nitride sub-layers.

11. The device according to claim 1, wherein each first insulating spacers is separated from the insulating layer by a second insulating spacer, at least one of the first and second insulating spacers including a plurality of sub-layers.

12. A method of manufacturing an electronic device, comprising:
forming trenches in a first layer of the electronic device;
depositing a layer made of an electrically-resistive material;
depositing a first insulating layer on the layer made of the electrically-resistive material;
performing an anisotropic etching of the first insulating layer and of the layer made of the electrically-resistive material leaving them remaining only on flanks of the first layer, a remaining portion of the first insulating layer being rounded;
forming, in the layer of the electrically-resistive material, resistive heating elements;
forming, in the first insulating layer, first insulating spacers;
entirely filling the trenches with an insulating oxide layer; and
removing an upper portion of the insulating layer, of the first insulating spacers, and of the resistive heating elements to expose a first surface of the first layer, so as to form a plurality of memory cells arranged in an array of rows and columns.

13. The manufacturing method according to claim 12, wherein, during the entirely filling the trenches, the insulating layer is deposed in contact with:
first insulating spacers covering two successive resistive heating elements of a same row; and
a side flank, opposite to the vertical portion, of the horizontal portion of two successive resistive heating elements of a same row.

14. The manufacturing method according to claim 12, wherein, during the depositing the first insulating layer on the layer of the electrically-resistive material, the first insulating layer is deposited by a pulsed plasma-enhanced chemical vapor deposition method.

15. The manufacturing method according to claim 14, wherein, during the depositing the first insulating layer, a power of the plasma alternates between a high power and a low power.

16. The manufacturing method according to claim 14, wherein the first insulating layer is formed by the successive deposition of a plurality of sub-layers.

17. The manufacturing method according to claim 16, wherein the sub-layers have a thickness smaller than 15 nm.

18. The manufacturing method according to any of claim 12, further comprising, after the removing the upper portion of the insulating layer:
depositing an upper electrode on the layer made of the phase-change material;
depositing a masking layer on the upper electrode;
forming rows in the masking layer, the upper electrode, and the layer made of the phase-change material, by etching; and
depositing an encapsulation layer covering an upper surface of the masking layer and the side flanks of the masking layer, of the upper electrode, and of the layer made of the phase-change material.

19. The manufacturing method according to claim 18, wherein the masking layer and the encapsulation layer are deposited according to a pulsed plasma-enhanced chemical vapor deposition method.

20. The manufacturing method according to claim 12, comprising, between the performing the anisotropic etching and the entirely filling the trenches with the insulating oxide layer, depositing a second insulating layer on and in contact with the first insulating spacers and forming, in the second insulating layer, second insulating spacers by anisotropic etching the second insulating layer;
and wherein at least one of the first and second insulating spacer are formed by a pulsed plasma-enhanced chemical vapor deposition method.
